(19) United States
(12) Patent Application Publication
(10) Pub. No.: US 2026/0170218 A1
(43) Pub. Date: Jun. 18, 2026

(54) METHOD FOR EM CIRCUIT SIMULATION WITH SUPERLOOPS

(71) Applicant: Sonnet Software, Inc., Syracuse, NY (US)

(72) Inventor: Brian Rautio, Syracuse, NY (US)

(73) Assignee: Sonnet Software, Inc., Syracuse, NY (US)

(21) Appl. No.: 19/418,100

(22) Filed: Dec. 12, 2025

Related U.S. Application Data
(60) Provisional application No. 63/733,802, filed on Dec. 13, 2024.

(51) Int. Cl. G06F 30/367

(52) U.S. Cl. CPC G06F 30/367

(57) ABSTRACT

A computer-implemented method of constructing a complete current basis for electromagnetic simulation of an electrical circuit includes the steps of generating a tree spanning all vertices of the circuit to provide a first set of degrees of freedom for a subset of edges, generating loops for two-by-two vertex sets to provide a second set of degrees of freedom, identifying edges with degrees of freedom provided by the loops, and generating superloops for edges lacking degrees of freedom due to circuit features such as vias or holes; thereby eliminating the need for computationally intensive hole detection by directly identifying edges requiring superloops; ensuring a complete basis for accurate electromagnetic simulation while significantly improving computational efficiency.

### CROSS-REFERENCE TO RELATED APPLICATION(S)

The present application relates and claims priority to Applicant's U.S. Provisional Patent Application Ser. No. 63/733802, filed Dec. 13, 2024, the entirety of each of which is hereby incorporated by reference.

### FIELD OF INVENTION

This disclosure relates generally to electromagnetic (EM) circuit simulation technologies, and in particular to methods for constructing a complete current basis using trees, loops, and superloops.

### BACKGROUND

Electromagnetic simulation software typically works by dividing a given circuit into a set of sections called “vertices” (also called, faces, nodes, or ramps). The current throughout the circuit is then modeled by calculating the current flowing between vertices within the circuit. An example of this is shown in FIG. 1, which depicts a small portion of a modeled circuit 100 divided into vertices 102a-102d. Current flows between each vertex, but here it is simplified to show current 104 flowing between vertices 102a and 102b. To flow between two vertices, the current passes through edge 106. For the purposes of this disclosure, an “edge” represents a connection (a shared border) between two vertices and thus a path over which current can flow from one vertex to another. (An “edge” is also referred to as a “basis function” or “subsection” within the art.)

Not shown in FIG. 1 is current that flows between every other vertex. Only current 104 is depicted for simplicity. However, to appropriately simulate the circuit, the current flow between each contiguous vertex must be modeled. More particularly, every edge requires a “Degree of Freedom” (DoF): i.e., an independent value of current (e.g., 1 Amp/m) assigned to the edge.

If even a single DoF is not properly assigned, in a circuit with millions of edges, the final solution will be materially incorrect and thus invalid. Calculating current in a circuit without a DoF assigned to each edge is known as an “incomplete basis.” Given the consequences of an incomplete basis, it is vitally important that each edge have the appropriate DoF assigned to each edge before calculating the final solution.

To model the degrees of freedom within the circuit, a process known in the art as “loop and tree” can be employed. In this process, independent “trees” and “loops” are simulated. A tree is a current path through the vertices of circuit that never “meets” itself, i.e., the current never flows back into a vertex through which it has already traveled. An example of a tree is shown in FIG. 2. As can be seen, tree 202 exhibits purely divergent behavior—each path through the circuit 200 never flows back into itself.

Any number of possible trees exist for a given circuit. For the circuit to be appropriately simulated, only one valid tree that spans all vertices is necessary. A DoF is determined for each edge traversed by the tree. However, because the tree does not flow back into itself, the tree does not, by itself, result in a complete basis. Edges between parallel paths of the tree, for example, will not have an assigned DoF.

Loops are used to account for the DoFs missing from a tree. A loop is a current path in which current flows in a 2×2 set of vertices, traveling through each vertex before flowing back into itself. For example, as shown in FIG. 3, the current (represented by arrows 304a-304d) flows clockwise across edges 306a-306d of the 2×2 set of vertices 302a-302d before flowing back into itself. (As will be understood by a person of ordinary skill in the art, and as used in this disclosure and as shown in FIG. 3, a 2×2 set of vertices for which a loop can be employed is a 2×2 set of vertices that surrounds a quadripoint.) Algorithmically, loops are typically found by beginning at a vertex and determining whether edges exist in such a clockwise arrangement around it. If such an arrangement of edges exists (i.e., corresponding to a 2×2 set of vertices), then a loop exists. Each loop provides one DoF not captured by the tree.

The circuit is simulated by superposing the DoFs calculated for the tree and the loops. The loop and tree method is generally understood in the art.

In general, the loop and tree method captures all vertices and edges, except for two scenarios: (1) a via and (2) a “hole.” A via is a “vertical” connection between vertices, i.e., a conductor that connects vertices disposed on different layers of the circuit. This can be seen, for example, in FIG. 4, which includes vias 402a, 402b that extend between layers 404a, 404b, and 406. Loops only travel horizontally (i.e., within a layer) and thus do not capture the via. A hole is a space without a vertex (or without vertices, as the space can be any size and shape) but that is bordered by vertices on all sides. FIG. 4 further depicts a hole 410, which is a space (absence of a vertex) bordered by vertices 408a-408e. A tree will not capture DoFs for all edges of vertices surrounding the hole because the tree cannot flow back into itself. And there are no loops around the hole because the hole prevents forming a 2×2 set of vertices with a quadripoint.

Circuits with vias and holes require “superloops” to form a complete basis. A superloop is a loop that can travel anywhere in the circuit (not just a 2×2 set of vertices), including vertically. For a circuit with vias and holes, a complete basis is formed by the combination of a tree, regular loops, superloops due to vias, and superloops due to holes. The use of superloops to account for vias and holes is generally understood in the art.

While vias are easily identified in a circuit structure, holes are more difficult. In many common cases, circuit design is performed additively, rather than fabricating a solid conductive layer and identifying portions to remove. Thus, holes cannot rely on automatic identification, and they may arise naturally during the design process without the knowledge of the designer.

Additionally, while the total number of edges included in a circuit is known, the edges that do not have a DoF assigned because of trees and loops alone are not known a priori. Stated differently, because the location of holes is not known, it is also not known where superloops are required to find the DoFs for certain edges around the holes.

Attempts to solve this problem have previously focused on identifying the location of holes within the circuit. Identifying the locations of holes typically requires examining each combination of vertices within a circuit to determine whether edges enclose a boundary. While conceptually simple, this process requires extensive computational effort in a circuit with millions of vertices.

There exists a need in the art to identify edges that require a superloop to provide the missing degree of freedom because of the existence of the hole, without requiring first identifying the location of the hole.

### SUMMARY

According to an aspect, a computer-implemented method for constructing a complete current basis for an electromagnetic simulation of an electrical circuit, the electrical circuit comprising a plurality of vertices and a plurality of edges, includes the steps of: generating a tree that spans all vertices of the electrical circuit, the tree providing a first set of computed degrees of freedom for a first subset of edges of the plurality of edges, the first subset of edges comprising each edge traversed by the tree; generating a set of loops for each two-by-two set of vertices of the electrical circuit, the set of loops providing a second set of computed degrees of freedom; identifying a second subset of edges of the plurality of edges, wherein the second subset of edges comprise each edge of the plurality of edges for which the set of loops provides a degree of freedom; and generating a superloop for each edge of the plurality of edges not within the first subset of edges or the second subset of edges, such that a complete basis is provided for the electrical circuit.

In an example, the vertices and the edges are indexed within a grid that spans the electrical circuit, wherein generating the tree comprises selecting edges in ascending edge-index order until all vertices are spanned. In this example, identifying the second subset of edges comprises: for each loop, selecting the edge with the greatest index that is not traversed by the tree or by any previously processed loop.

In another example, generating the tree comprises selecting edges in descending edge-index order until all vertices are spanned. In this example, identifying the second subset of edges comprises: for each loop, selecting the edge with the lowest index that is not traversed by the tree or by any previously processed loop.

In an example, identifying the second subset of edges comprises: sequentially identifying edges for contiguous loops disposed between the same branches of a tree.

In an example, identifying the second subset of edges comprises: identifying edges for loops that have three edges for which a tree provides degrees of freedom before identifying edges for loops for which the tree provides only two degrees of freedom.

According to another aspect, a non-transitory computer-readable storage medium includes a set of non-transitory computer-readable instructions that, when executed by a processing system, direct the system to perform the sequence of operations of the computer-implemented method recited above.

### BRIEF DESCRIPTION OF THE FIGURES

FIG. 1 depicts a schematic illustration of a portion of an electromagnetic (EM) circuit model showing vertices, edges, and an example current flowing across a single edge between two vertices.

FIG. 2 depicts a diagram depicting an example tree spanning vertices of a circuit.

FIG. 3 depicts a diagram illustrating a regular loop formed across a two-by-two set of vertices.

FIG. 4 depicts a multi-layer circuit diagram illustrating vias connecting different layers and an example hole bordered by surrounding vertices.

FIG. 5 depicts a plan view of an example circuit with vertices and indexed edges, showing an example tree and an example set of regular loops.

FIG. 6 depicts a schematic illustrating contiguous loops disposed between branches of a tree, demonstrating edge selection considerations to ensure each loop is assigned an available edge, according to an example.

FIG. 7 depicts a flow chart of a computer-implemented method for EM circuit simulation, according to an example.

FIG. 8A is a graphical representation of the circuit of FIG. 4 highlighting the tree; FIG. 8B is the same representation highlighting the regular loops; FIG. 8C is the representation with edges lacking degrees of freedom removed; and FIG. 8D is the representation after restoration of all missing degrees of freedom via superloops.

FIG. 9 is a top view of the circuit geometry of FIG. 4.

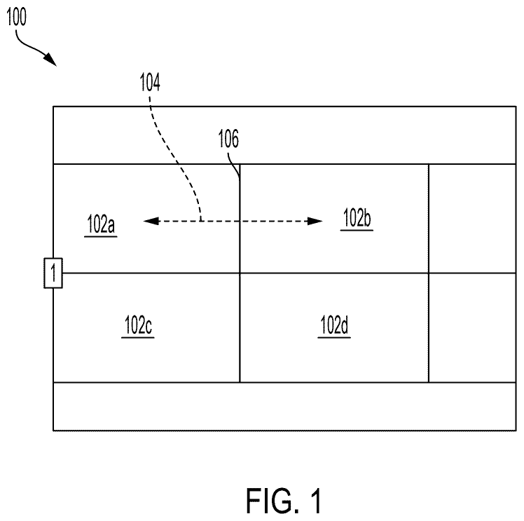

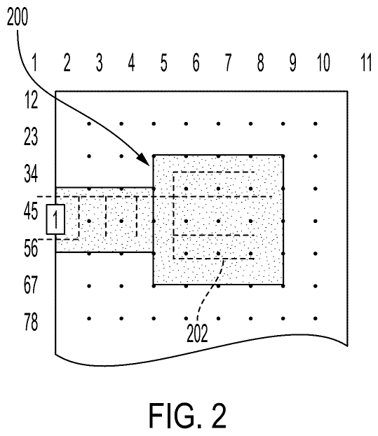

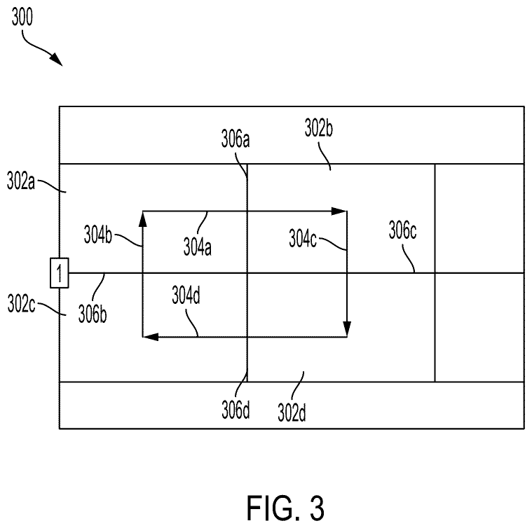

### DETAILED DESCRIPTION

The present disclosure relates generally to methods and systems for electromagnetic (EM) circuit simulation, and more particularly to techniques for constructing a complete current basis for EM simulation using trees, loops, and superloops to account for missing degrees of freedom in electrical circuits. The described technology is particularly applicable to circuits with complex structures, such as those containing vias or holes, where traditional simulation methods required computationally demanding algorithms to identify holes for which superloops are employed to provide a complete basis function.

The disclosed method addresses these limitations by introducing a novel approach for efficiently identifying and resolving missing degrees of freedom (DoFs) without requiring the explicit identification of holes. Rather than concentrating on locating holes, the described method identifies edges that already have DoFs assigned by trees and regular loops. By systematically accounting for these edges, the remaining edges that lack DoFs are revealed. These edges, which correspond to missing DoFs caused by both holes and vias, can then be addressed using superloops. This approach removes the need for computationally intensive hole detection, leading to a significant reduction in the processing time and resources required for electromagnetic (EM) circuit simulation.

In various examples, the disclosed method employs a systematic algorithmic process to generate trees and regular loops, followed by the identification of edges with known DoFs. The described method incorporates rules for selecting edges of loops to ensure that all loops are assigned a DoF without conflicts. For example, edges of loops can be selected in descending or ascending order of edge indices, depending on the tree generation method, to avoid scenarios where a loop is left without an available edge. Once the edges with known DoFs are identified, the remaining edges are resolved using superloops, which can traverse any part of the circuit, including vertically, to restore the missing DoFs. This approach not only ensures a complete basis for the circuit but also achieves computational efficiency by avoiding the need to explicitly locate holes or analyze their causes. The described method thus provides a robust and scalable solution for electromagnetic (EM) circuit simulation.

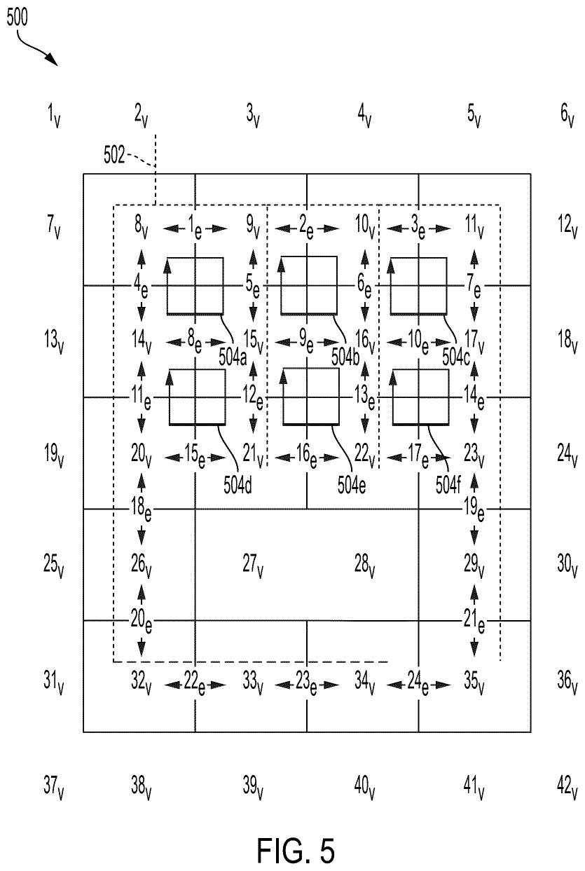

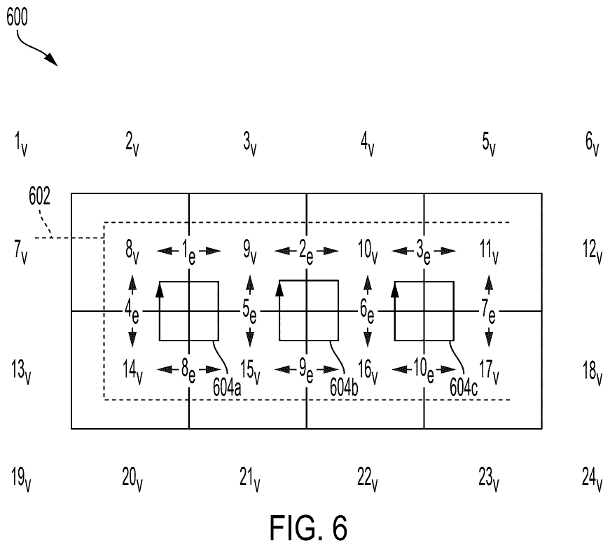

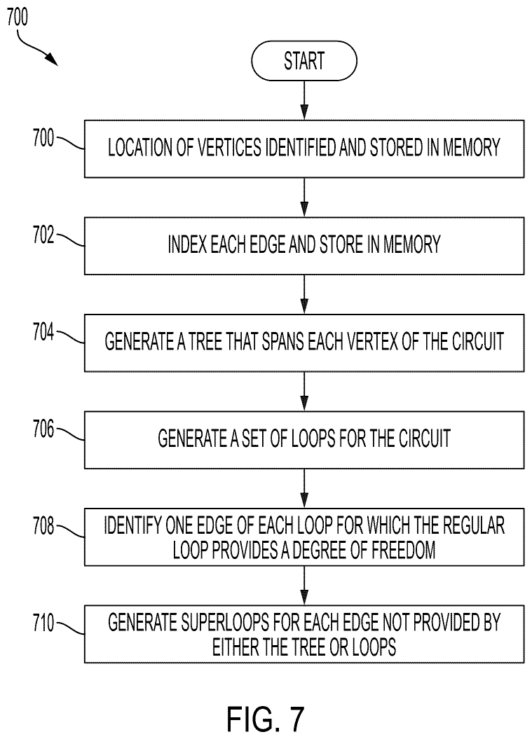

Turning now to FIG. 5, there is shown an example circuit 500. FIG. 7 depicts a computer-implemented method (software) for electromagnetic simulation of an electrical circuit, according to an example. The steps of FIG. 7 are described in conjunction with the example FIG. 5 (and with FIG. 6), though it should be understood that these steps can apply to any suitable circuit geometry. The steps of FIG. 7 can be stored on a non-transitory storage medium and executed on one or more processors. The results of the simulation can be displayed to a user, for example, on a monitor. Aspects of EM software that are known in the art will not be described in detail.

At step 700, the location of the vertices can be identified and stored in memory. As shown in FIG. 5, the circuit includes eighteen vertices. For example, the vertices can be indexed within a grid that spans the dimension of the entire circuit, including an additional row to the top and bottom and an additional column to the left and to the right. (These indexes have been given the subscript v to distinguish the vertex index from the edge index, which will be described below). The grid is numbered like words in a book: left to right in lines arranged from top to bottom. Using this method, the top-left vertex is indexed at 8v. All existing vertices within the circuit can thus be stored in memory in a single array according to vertex index number (e.g., 8v, 9v, 10v, 11v, 14v, 15v, etc.). It should be understood that other methods of indexing the vertices of the circuit can be used. For example, without changing the inventive aspects described herein, the indices could be ordered right to left, bottom to top. Other variations are conceivable and will be understood by a person of ordinary skill in the art in conjunction with a review of this disclosure.

In this example, at step 702, each edge is indexed in similar fashion: left to right and top to bottom. Again, an edge is a connection between two vertices and thus a path over which current can flow from one vertex to another. Thus, beginning at the top left in FIG. 5, an edge exists between vertices 8v and 9v. This edge is indexed as edge 1e. Similarly, edge 2e exists between vertices 9v and 10v, and so on. Edge 3e exists between vertices 10v and 11v, and so on. There is no edge at top of 8v because it is not a connection to another vertex. The edges can likewise be stored in memory in a single array according to according to edge number (e.g., 1e, 2e, 3e, 4e, etc.). Further, it should be understood that other methods of indexing the edges can be used. Like the vertex indices, without changing the inventive aspects described herein, the edge indices could be ordered right to left, bottom to top. Other variations are conceivable and will be understood by a person of ordinary skill in the art in conjunction with a review of this disclosure.

As can be seen, the circuit does not include vertices at 27v or 28v. These spaces constitute a “hole” in the circuit and thus will create a missing degree of freedom from trees and regular loops, as will be described below.

At step 704, a tree is generated for the circuit which encompasses the maximum possible number of Degrees of Freedom while remaining irrotational. In an example, this is shown by tree 502 (shown as a dashed line in FIG. 5). As described above, a tree is a current path through the vertices of circuit that never “meets” itself, i.e., the current never flows back into a vertex through which it has already traveled. While multiple possible valid trees exist for a given circuit, it is only necessary to find a single valid tree that includes the maximum number of Degrees of Freedom. A DoF is assigned for each and every edge traversed by the tree. Because the tree does not traverse every edge, the tree finds degrees of freedom for a subset of the edges of the circuit. In this example, the tree 502 has been generated according to ascending edge index. Thus, the tree first extends from 1e to 3e, then through 4e, then 5e, then 6e, and 7e, and so on. Following this pattern, the tree extends down and around the hole (denoted by indices 27v and 28v) but does not extend through edge 24e. It should be understood, however, that any suitable method for generating a tree can be used.

Next, at step 706, a set of regular loops 504 are generated for the circuit. Any suitable method for generating regular loops can be used. As described above, a loop is a current path in which current flows in a 2×2 set of vertices, traveling through each vertex before flowing back into itself. Algorithmically, loops are typically found by beginning at a vertex and determining whether edges exist in such a clockwise arrangement around it. If such an arrangement of edges exists (i.e., corresponding to a 2×2 set of vertices), then a loop exists. Each loop provides one DoF not captured by the tree. The set of loops generated at step 706 provides degrees of freedom a second subset of edges of the circuit.

As can be seen in FIG. 5, no loops are generated that would provide a degree of freedom for edge 24e and thus this edge has no degree of freedom resulting from the hole in the circuit, after the tree 502 and regular loops 504 are generated.

As mentioned above, rather than attempting to find the hole, which is computationally inefficient, Applicant has recognized that it is simpler and significantly more efficient to affirmatively identify the edges for which regular loops and the tree provide DoFs. Once all edges are identified with known degrees of freedom, the edges without DoFs provided by loops or tree require superloops to solve. Thus, by identifying all edges with known DoFs, the edges that require superloops become readily identifiable without identifying the cause of the missing DoF. In other words, identifying edges with known degrees of freedom will reveal DoFs missing as a result of both holes and vias, but will not identify why the degree of freedom is missing. Critically, it is not necessary for the algorithm to recognize why the degree of freedom is missing, as known methods can generate superloops for a missing degree of freedom without a priori knowledge of the cause of a missing degree of freedom. In this way, Applicant has thus recognized a computationally efficient method of addressing missing degrees of freedom caused by holes (or by vias) without first identifying the location of holes within the circuit.

Thus, at step 708, one edge of each regular loop is identified as the edge for which the regular loop provides a degree of freedom. Once this process has been completed, the combined edges traversed by the tree and the identified edges of the regular loop provide a comprehensive accounting of edges with known degrees of freedom. In FIG. 5, the identified edges of regular loops 504a-504f are shown in bold. It will be understood that the identified edges are necessarily edges that do not have degrees of freedom provided by the tree.

It will also be apparent to a person of ordinary skill in the art that certain regular loops will have more than one edge that can be identified as the edge for which the loop provides the DoF. For example, loop 504d has two edges that are not solved by tree 502, i.e., edges 8e and 15e. Both edges are thus candidates to be edge for which loop 504d provides a degree of freedom. This presents several problems. For example, if edge 8e is identified as solved by loop 504d before any edge of loop 504a is solved, then all edges of loop 504a have degrees of freedom provided by tree 502 or another loop, and no edge of loop 504a can be identified as the edge for which loop 504a provides a degree of freedom. This can be resolved, for example, by identifying edges for loops that have three edges for which a tree provides degrees of freedom before identifying edges for loops for which the tree provides only two degrees of freedom. This means that the edges for loops must be identified with respect to the degrees of freedom already provided by the try. In the example of FIG. 5, the edge for loops 504a, 504b, and 504c must be identified before 504d, 504e, and 504 f.

Similarly, if a loop is bordered by two loops, it is necessary that the candidate edges of the bordered loop are not taken by the surrounding loops. For example, looking at FIG. 6, loop 604b is between loop 604a and loop 604c. If the degree of freedom of edge 5e is identified as provided by loop 604a, it is necessary that edge 6e is not identified as being provided by loop 604c, which would result in loop 604b having no available edges to identify. This can be resolved, for example, by sequentially identifying edges for contiguous loops disposed between the same branches of a tree. Thus, if the edge is identified for loop 604a, then loop 604b, then loop 604c, this avoids the problem of identifying edges for loops which in a manner that renders another loop without an available edge.

The above rules for selecting edges of the loops require identifying certain features of the tree, or the position of the loops within the tree before identifying the edges. In practice, however, edge locations are stored in arrays and identifying the situations identified above can be challenging. Thus, in an alternative example, if the tree was generated according to ascending edge index (as described above), the edges of regular loops can be identified by progressing through the circuit loop-by-loop, identifying the edge by descending edge index. Thus for each loop, begin at the edge with the highest index and progress to the lowest index, identifying the first available edge (i.e., not already determined by the tree or another loop). For example, in FIG. 5 for loop 504a (which includes the lowest edge index), begin at edge 8e, since this is the highest index, check to determine whether this edge is available, before progressing to edge 5e, then 4e, and then 1e. Because 8e is not determined by the tree or another loop, this edge is selected as the edge for which loop 504a determined the degree of freedom. Next, for loop 504b, edge 9e is searched first and is selected. This is repeated for the remaining loops in the circuit. If the tree were generated by descending edge index, then the edges of loops could be selected by ascending edge index. The loops are taken in order of lowest available edge index. Thus, 504a is examined first since it has the lowest edge index 1e. Then, 504b is examined since it includes the next lowest available edge, 2 e. Next, 504c, then 504d, etc. This may alternatively be stated as moving to the loop with the lowest top edge index, since, in the edge indexing method described, the lowest edge index is located on top. Within each loop, the edges are examined in descending order, as described above. This method provides a solution that does not result in any loop having no available edges to select.

It should be understood that a variety of methods of generating trees are possible, and that the method of selecting the edges of the regular loops—while avoiding a solution that does not result in any loop having no available edges to select—will depend upon the manner that the tree is generated. Such other methods of selecting edges are within the scope of this disclosure.

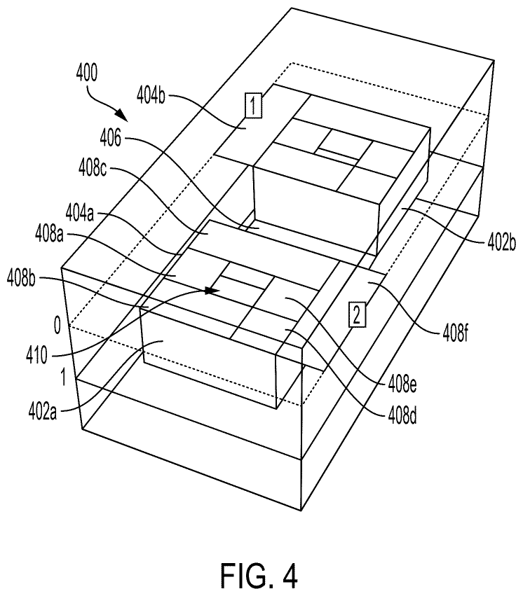

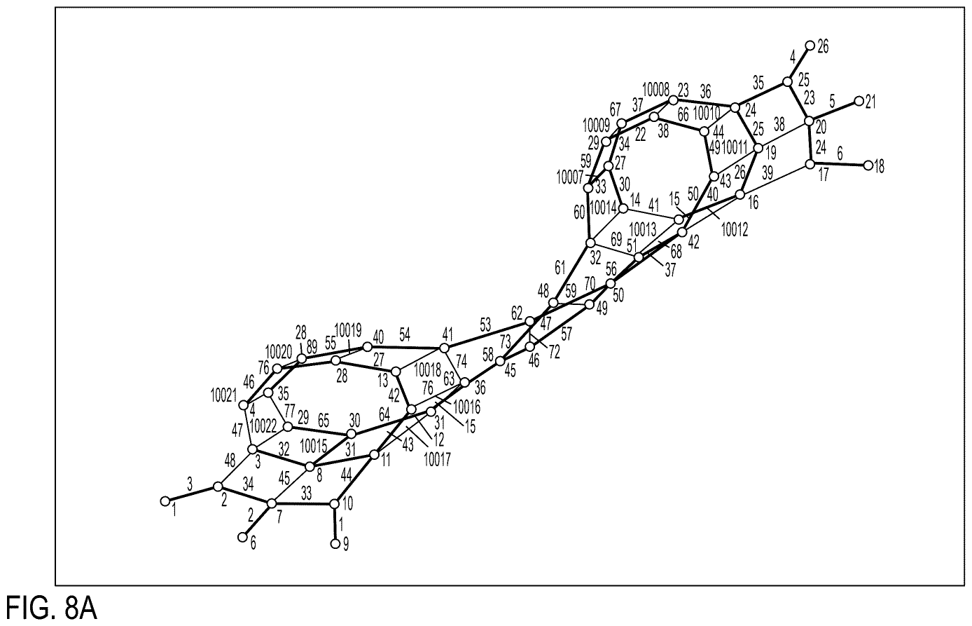

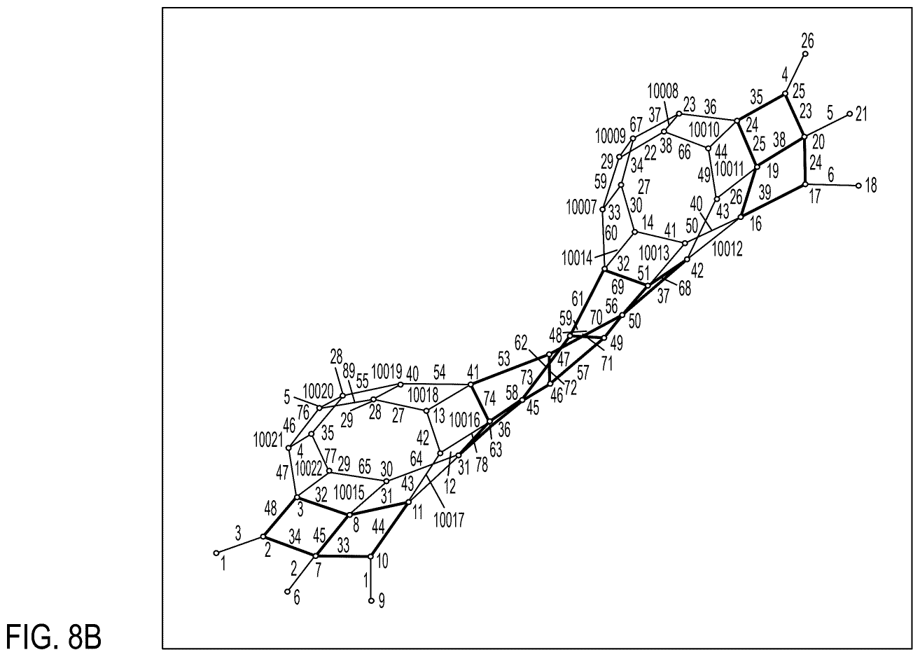

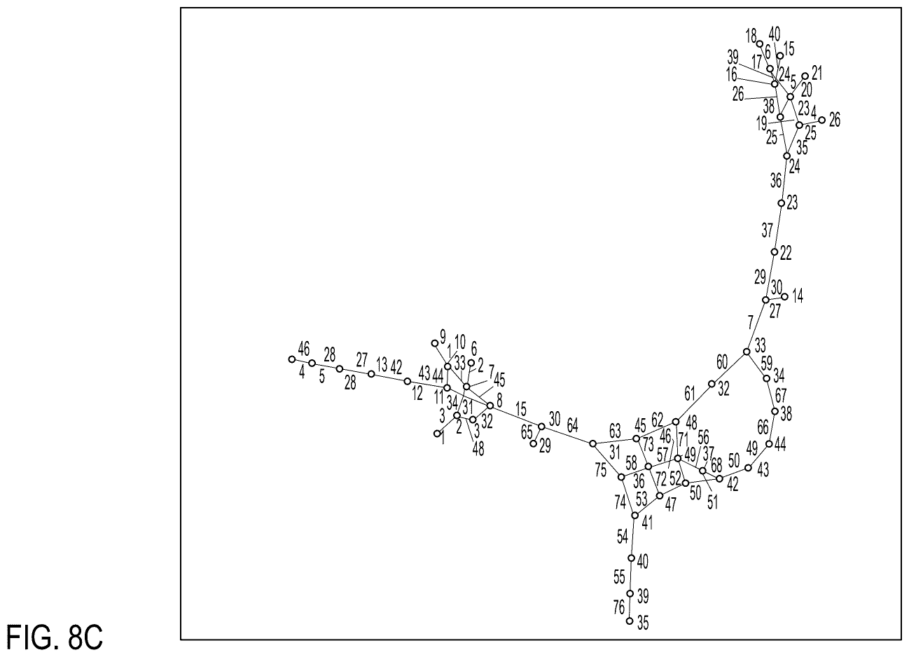

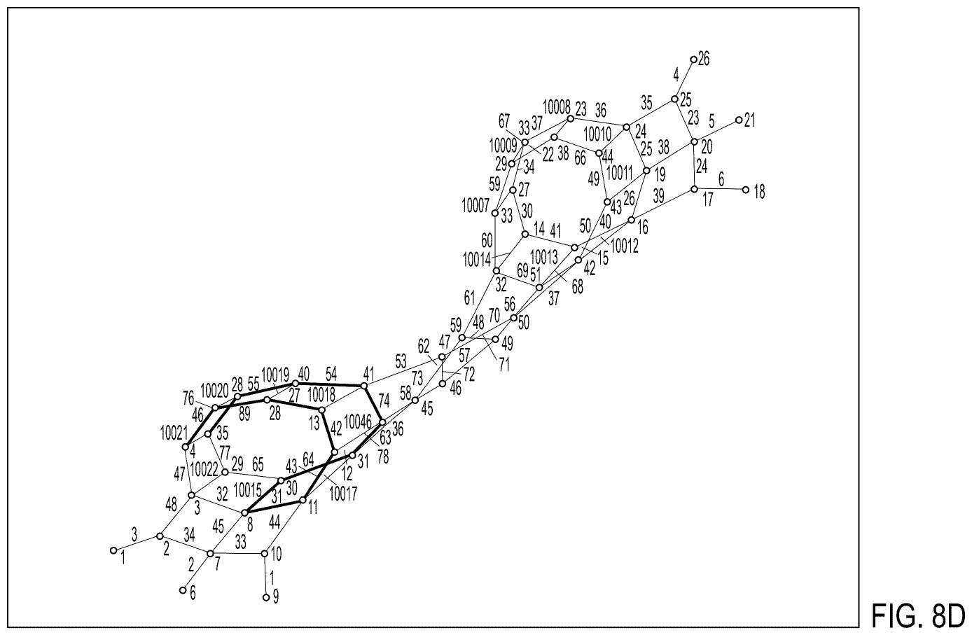

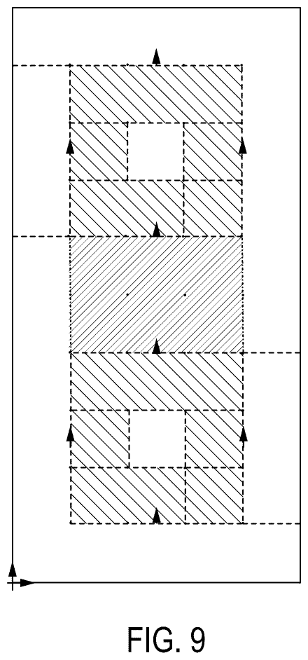

Once the degrees of freedom provided by the regular loops are identified, at step 710, edges that do not have degrees of freedom provided by either the tree or the regular loops are found using superloops (i.e., superloops are found for each edge not in the subset of edges found by the tree or the subset of edges found by the regular loops). For example, FIG. 8A depicts a graphical (i.e., relating to graph theory) view of the circuit of FIG. 4, with the tree found for the circuit highlighted. In the graphical view, the “nodes” of the view represent the vertices of the circuit, and the lines represent the edges. FIG. 8B depicts the same graphical view with the regular loops highlighted. (FIG. 9 depicts a top view of the geometry in FIG. 4.) FIG. 8C represents the graph with all edges that need a superloop to restore their DOF removed. These edges are restored one by one as suitable superloops are found, resulting in FIG. 8D, the graph after all necessary superloops are found, including a highlight of a superloop which restores the DOF for edge 10021. Any suitable method for finding a superloop path can be used once the missing edges are known.

Rather than concentrating on identifying the location of holes, the described technique systematically identifies edges that already have degrees of freedom (DoFs) assigned by trees and regular loops. By considering these edges, the remaining edges that lack DoFs are revealed. These edges, which correspond to missing DoFs caused by both holes and vias, are then resolved using superloops. This approach removes the need for computationally expensive hole detection algorithms, significantly enhancing the efficiency of electromagnetic (EM) circuit simulation. By focusing on the identification of edges requiring superloops, the described method provides a robust, scalable, and efficient solution for electromagnetic (EM) circuit simulation, enabling accurate modeling of circuits with complex structures.

The steps of the methods described in this disclosure can be performed in any suitable order unless otherwise indicated or clearly contradicted by context. For example, the trees and loops can be generated prior to ordering the circuit vertices/edges within the grid described. In other words, the grid can be applied after the tree/loops are generated—i.e., the vertices and/or edges can be renumbered according to the grid. Further, the grid can be applied to the tree in a manner that avoids any loop having no available edges to select, given the method of selecting the loops/edges.

While several inventive embodiments have been described and illustrated herein with reference to certain exemplary embodiments, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein (and it will be understood by one skilled in the art that various changes in detail may be effected therein without departing from the spirit and scope of the invention as defined by claims that can be supported by the written description and drawings). More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto; inventive embodiments may be practiced otherwise than as specifically described and claimed. Further, where exemplary embodiments are described with reference to a certain number of elements it will be understood that the exemplary embodiments can be practiced utilizing either less than or more than the certain number of elements.

All references, including publications, patent applications, and patents, cited herein are hereby incorporated by reference to the same extent as if each reference were individually and specifically indicated to be incorporated by reference and were set forth in its entirety herein.

All definitions, as defined and used herein, should be understood to control over dictionary definitions, definitions in documents incorporated by reference, and/or ordinary meanings of the defined terms.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

Approximating language, as used herein throughout the specification and claims, may be applied to modify any quantitative representation that could permissibly vary without resulting in a change in the basic function to which it is related. Accordingly, a value modified by a term or terms, such as “about” and “substantially”, are not to be limited to the precise value specified. In at least some instances, the approximating language may correspond to the precision of an instrument for measuring the value. Here and throughout the specification and claims, range limitations may be combined and/or interchanged; such ranges are identified and include all the sub-ranges contained therein unless context or language indicates otherwise.

The recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate embodiments of the invention and does not impose a limitation on the scope of the invention unless otherwise claimed.

No language in the specification should be construed as indicating any non-claimed element as essential to the practice of the invention.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

It will be apparent to those skilled in the art that various modifications and variations can be made to the present invention without departing from the spirit and scope of the invention. There is no intention to limit the invention to the specific form or forms disclosed, but on the contrary, the intention is to cover all modifications, alternative constructions, and equivalents falling within the spirit and scope of the invention, as defined in the appended claims. Thus, it is intended that the present invention cover the modifications and variations of this invention provided they come within the scope of the appended claims and their equivalents.

1. A computer-implemented method for constructing a complete current basis for an electromagnetic simulation of an electrical circuit, the electrical circuit comprising a plurality of vertices and a plurality of edges, comprises:
generating a tree that spans all vertices of the electrical circuit, the tree providing a first set of computed degrees of freedom for a first subset of edges of the plurality of edges, the first subset of edges comprising each edge traversed by the tree;
generating a set of loops for each two-by-two set of vertices of the electrical circuit, the set of loops providing a second set of computed degrees of freedom;
identifying a second subset of edges of the plurality of edges, wherein the second subset of edges comprise each edge of the plurality of edges for which the set of loops provides a degree of freedom; and
generating a superloop for each edge of the plurality of edges not within the first subset of edges or the second subset of edges, such that a complete basis is provided for the electrical circuit.

2. The computer-implemented method of claim 1, wherein the vertices and the edges are indexed within a grid that spans the electrical circuit, wherein generating the tree comprises selecting edges in ascending edge-index order until all vertices are spanned.

3. The computer-implemented method of claim 2, wherein identifying the second subset of edges comprises: for each loop, selecting the edge with the greatest index that is not traversed by the tree or by any previously processed loop.

4. The computer-implemented method of claim 1, wherein the vertices and the edges are indexed within a grid that spans the electrical circuit, wherein generating the tree comprises selecting edges in descending edge-index order until all vertices are spanned.

5. The computer-implemented method of claim 4, wherein identifying the second subset of edges comprises: for each loop, selecting the edge with the lowest index that is not traversed by the tree or by any previously processed loop.

6. The computer-implemented method of claim 1, wherein identifying the second subset of edges comprises: sequentially identifying edges for contiguous loops disposed between the same branches of a tree.

7. The method of claim 1, wherein identifying the second subset of edges comprises:
identifying edges for loops that have three edges for which a tree provides degrees of freedom before identifying edges for loops for which the tree provides only two degrees of freedom.

8. The method of claim 1, further comprising the step of displaying the electromagnetic simulation to a user via a display.

9. A non-transitory storage medium storing program code for constructing a complete current basis for an electromagnetic simulation of an electrical circuit, the electrical circuit comprising a plurality of vertices and a plurality of edges, the program code comprising the steps of:
generating a tree that spans all vertices of the electrical circuit, the tree providing a first set of computed degrees of freedom for a first subset of edges of the plurality of edges, the first subset of edges comprising each edge traversed by the tree;
generating a set of loops for each two-by-two set of vertices of the electrical circuit, the set of loops providing a second set of computed degrees of freedom;
identifying a second subset of edges of the plurality of edges, wherein the second subset of edges comprise each edge of the plurality of edges for which the set of loops provides a degree of freedom; and
generating a superloop for each edge of the plurality of edges not within the first subset of edges or the second subset of edges, such that a complete basis is provided for the electrical circuit.

10. The non-transitory storage medium of claim 9, wherein the vertices and the edges are indexed within a grid that spans the electrical circuit, wherein generating the tree comprises selecting edges in ascending edge-index order until all vertices are spanned.

11. The non-transitory storage medium of claim 10, wherein identifying the second subset of edges comprises: for each loop, selecting the edge with the greatest index that is not traversed by the tree or by any previously processed loop.

12. The non-transitory storage medium of claim 9, wherein the vertices and the edges are indexed within a grid that spans the electrical circuit, wherein generating the tree comprises selecting edges in descending edge-index order until all vertices are spanned.

13. The non-transitory storage medium of claim 12, wherein identifying the second subset of edges comprises: for each loop, selecting the edge with the lowest index that is not traversed by the tree or by any previously processed loop.

14. The non-transitory storage medium of claim 9, wherein identifying the second subset of edges comprises: sequentially identifying edges for contiguous loops disposed between the same branches of a tree.

15. The non-transitory storage medium of claim 9, wherein identifying the second subset of edges comprises: identifying edges for loops that have three edges for which a tree provides degrees of freedom before identifying edges for loops for which the tree provides only two degrees of freedom.

16. The non-transitory storage medium of claim 9, further comprising the step of displaying the electromagnetic simulation to a user via a display.
